(19) United States
(12) Patent Application Publication
(10) Pub. No.: US 2024/0079452 A1
(43) Pub. Date: Mar. 7, 2024

(54) VERTICAL TRANSISTOR STRUCTURES WITH OFFSET SPACERS

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/939,617

(22) Filed: Sep. 7, 2022

(51) Int. Cl. H01L 29/10; H01L 29/423; H01L 29/66

(52) U.S. Cl. CPC H01L 29/1033; H01L 29/1095; H01L 29/42364; H01L 29/66553

(57) ABSTRACT

A transistor structure is disclosed. The structure includes a first lower metal layer extending along one or more lateral directions. The structure includes a first upper metal layer in parallel with the first lower metal layer, wherein the first lower metal layer and the first upper metal layer are spaced from each other with a first isolation material. The structure includes a first channel extending from the first lower metal layer to the first upper metal layer. The structure includes a first dielectric spacer surrounded by the first channel and further by the first lower metal layer. The structure includes a second dielectric spacer also surrounded by the first channel and further by the first upper metal layer. The structure includes a first gate electrode surrounded by the first channel and vertically interposed between the first dielectric spacer and the second dielectric spacer.

### FIELD OF THE DISCLOSURE

This disclosure relates to microelectronic devices including semiconductor devices, transistors, and integrated circuits, including methods of microfabrication.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

One aspect of the present disclosure is directed to a transistor structure. The structure includes a substrate including a first region and a second region. The structure includes a first lower metal layer and a first upper metal layer in the first region, wherein the first lower metal layer and the first upper metal layer are spaced from each other with a first isolation material. The structure includes a first channel extending from the first lower metal layer to the first upper metal layer. The structure includes a first gate electrode surrounded by the first channel and vertically spaced from each of the first lower metal layer and the first upper metal layer. The structure includes a second lower metal layer and a second upper metal layer in second region, wherein the second lower metal layer and the second upper metal layer are spaced from each other with a second isolation material. The structure includes a second channel extending from the second lower metal layer to the second upper metal layer. The structure includes a second gate electrode surrounded by the second channel and vertically spaced from each of the second lower metal layer and the second upper metal layer.

The structure further includes a first dielectric spacer disposed below the first gate electrode; a second dielectric spacer disposed above the first gate electrode; a third dielectric spacer disposed below the second gate electrode; and a fourth dielectric spacer disposed above the second gate electrode. The first and second dielectric spacers are each surrounded by the first channel, and the third and fourth dielectric spacers are each surrounded by the second channel. The first dielectric spacer elevates a bottom surface of the first gate electrode away from the first lower metal layer, and the second dielectric spacer lowers a top surface of the first gate electrode away from the first upper metal layer. The third dielectric spacer elevates a bottom surface of the second gate electrode away from the second lower metal layer, and the fourth dielectric spacer lowers a top surface of the second gate electrode away from the second upper metal layer.

The first gate electrode has a first conductive type, and the second gate electrode has a second conductive type.

The structure further includes a first gate dielectric extending from the first lower metal layer to the first upper metal layer, and surrounded by the first channel; and a second gate dielectric extending from the second lower metal layer to the second upper metal layer, and surrounded by the second channel.

The first channel includes at least one of: indium oxide (In₂O₃), tin dioxide (SnO₂), zinc oxide (ZnO), or InGaZnO, and the second channel includes tin oxide (SnO)

The structure further includes a first via structure extending through the first upper metal layer and the first isolation material, and in electrical contact with the first lower metal layer; a second via structure extending through a dielectric spacer disposed above the first gate electrode, and in electrical contact with the first gate electrode; a third via structure in electrical contact with the first upper metal layer; a fourth via structure extending through the second upper metal layer and the second isolation material, and in electrical contact with the second lower metal layer; a fifth via structure extending through a dielectric spacer disposed above the second gate electrode, and in electrical contact with the second gate electrode; and a sixth via structure in electrical contact with the second upper metal layer.

Another aspect of the present disclosure is directed to a transistor structure. The structure includes a first lower metal layer extending along one or more lateral directions. The structure includes a first upper metal layer in parallel with the first lower metal layer, wherein the first lower metal layer and the first upper metal layer are spaced from each other with a first isolation material. The structure includes a first channel extending from the first lower metal layer to the first upper metal layer. The structure includes a first dielectric spacer surrounded by the first channel and further by the first lower metal layer. The structure includes a second dielectric spacer also surrounded by the first channel and further by the first upper metal layer. The structure includes a first gate electrode surrounded by the first channel and vertically interposed between the first dielectric spacer and the second dielectric spacer.

The first dielectric spacer elevates a bottom surface of the first gate electrode away from the first lower metal layer, and the second dielectric spacer lowers a top surface of the first gate electrode away from the first upper metal layer.

The structure further includes a first gate dielectric extending from the first lower metal layer to the first upper metal layer, and interposed between the first channel and a combination of the first dielectric spacer, the first gate electrode, and the second dielectric spacer.

The structure further includes a second lower metal layer extending along the one or more lateral directions; a second upper metal layer in parallel with the second lower metal layer, wherein the second lower metal layer and the second upper metal layer are spaced from each other with a second isolation material; a second channel extending from the second lower metal layer to the second upper metal layer; a third dielectric spacer surrounded by the second channel and further by the second lower metal layer; a fourth dielectric spacer also surrounded by the second channel and further by the second upper metal layer; and a second gate electrode surrounded by the second channel and vertically interposed between the third dielectric spacer and the fourth dielectric spacer. The first gate electrode has a first conductive type, and the second gate electrode has a second conductive type.

The structure further includes a third lower metal layer extending along the one or more lateral directions; a third upper metal layer in parallel with the third lower metal layer, wherein the third lower metal layer and the third upper metal layer are spaced from each other with a third isolation material; a third channel extending from the third lower metal layer to the third upper metal layer; a fifth dielectric spacer surrounded by the third channel and further by the third lower metal layer; a sixth dielectric spacer also surrounded by the third channel and further by the third upper metal layer; and a third gate electrode surrounded by the third channel and vertically interposed between the fifth dielectric spacer and the sixth dielectric spacer. The first gate electrode and the third gate electrode have an identical conductive type.

The first lower metal layer and the third lower metal layer are formed as a first one-piece structure, and the first upper metal layer and the third upper metal layer are formed as a second one-piece structure. The first lower metal layer and the third lower metal layer are isolated from each other, and the first upper metal layer and the third upper metal layer are isolated from each other.

Yet another aspect of the present disclosure is directed to a method for forming a transistor structure. The method includes forming a stack including a lower metal layer, an isolation material, and an upper metal layer, wherein the lower metal layer and the upper metal layer are spaced from each other with the isolation material. The method includes forming a first opening extending through the stack. The method includes lining an inner sidewall of the first opening with a first channel. The method includes sequentially forming a first dielectric spacer, a first gate electrode, and a second dielectric spacer in the first opening, wherein a combination of the first dielectric spacer, the first gate electrode, and the second dielectric spacer is surrounded by the first channel.

The first dielectric spacer elevates a bottom surface of the gate electrode away from the lower metal layer, and the second dielectric spacer lowers a top surface of the gate electrode away from the upper metal layer.

The method further includes forming a second opening extending through the stack; lining an inner sidewall of the second opening with a second channel; and sequentially forming a third dielectric spacer, a second gate electrode, and a fourth dielectric spacer in the second opening, wherein a combination of the third dielectric spacer, the second gate electrode, and the fourth dielectric spacer is surrounded by the second channel.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow chart of an example method for making a semiconductor device, in accordance with some embodiments.

FIGS. 2 to 17 each illustrate a top view or a cross-sectional view of a semiconductor device, during one of various fabrication stages, made by the method of FIG. 1, in accordance with some embodiments.

FIG. 18 illustrates a cross-sectional view of another semiconductor device, made by the method of FIG. 1, in accordance with some embodiments.

FIG. 19 illustrates a cross-sectional view of yet another semiconductor device, made by the method of FIG. 1, in accordance with some embodiments.

FIG. 20 illustrates a top view of yet another semiconductor device, made by the method of FIG. 1, in accordance with some embodiments.

FIG. 21 illustrates a top view of multiple contact structures formed for the semiconductor device of FIG. 20, in accordance with some embodiments.

### DETAILED DESCRIPTION

Disclosed herein are embodiments related to one or more transistor structures having a central vertical metal structure. In some embodiments, the vertical metal structure may occupy an innermost level of an opening forming a transistor structure and operatively function as the gate of said transistor structure. Based on such a vertical metal structure, advantageously, the transistor structures, as disclosed herein, may be formed as channel-all-around (CAA) or channel around gate (CAG) transistor structures, where a channel layer may wrap around this vertical metal gate structure. Based on such transistor structures, any number of the disclosed vertical metal structures can be laterally (e.g., side-by-side) arranged with each other and/or vertically stacked on top of one another, thereby forming an array of transistor structures having improved characteristics in an area efficient manner. In various embodiments, an arrangement of the channel layer formed around the metal structures can be flexibly configured. For example, the channel layer can have a single material (e.g., a conductive oxide material) or plural materials (e.g., a conductive oxide material wrapping around a two-dimensional (2D) material). In general, conductive oxide materials/2D materials can allow significant boost in performance relative to silicon (Si), such that transistor structures disclosed herein may have improved performances or characteristics (e.g., improved transconductance (gm), improved gain bandwidth (Ft), improved saturation current (Idsat), etc.).

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Likewise, although the Figures and aspects of the disclosure may show or describe devices herein as having a particular shape, it should be understood that such shapes are merely illustrative and should not be considered limiting to the scope of the techniques described herein. For example, although certain figures show various layers defining transistor structures or other electric structures in a circular configuration, other shapes are also contemplated, and indeed the techniques described herein may be implemented in any shape or geometry.

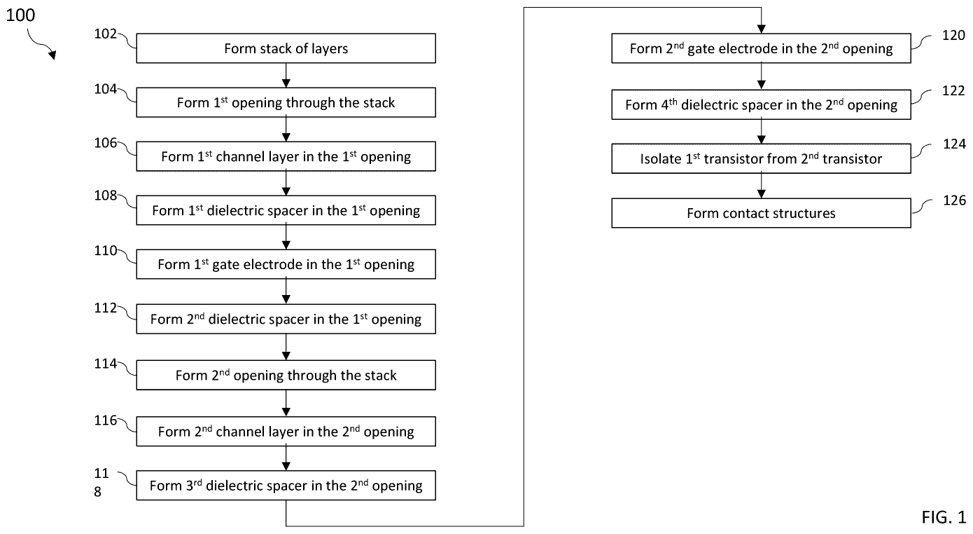

FIG. 1 illustrates a flowchart of an example method 100 for forming a semiconductor device based on a vertical metal structure. For example, the semiconductor device may include a number of transistors, and each of the transistor may be a vertical transistor with a channel layer wrapping around or otherwise surrounding at least a portion of the generally vertical metal structure that also operatively functions as a gate of the transistor. It is noted that the method 100 is merely an example, and is not intended to limit the present disclosure. Accordingly, it is understood that additional operations may be provided before, during, and after the method 100 of FIG. 1, and that some other operations may only be briefly described herein.

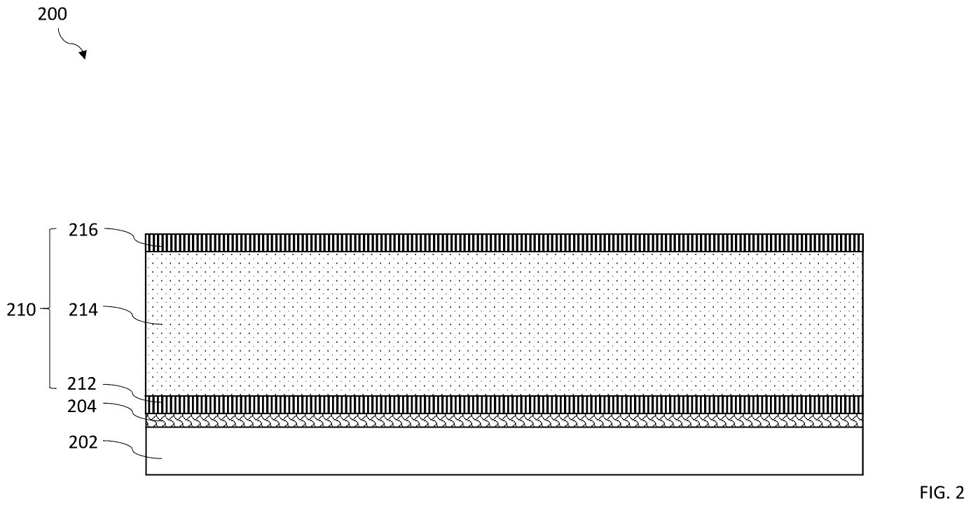

In various embodiments, operations of the method 100 may be associated with top views or cross-sectional views of an example semiconductor device 200 at various fabrication stages as shown in FIGS. 2 to 17, which will be discussed in further detail below. It should be understood that the semiconductor device 200, shown in FIGS. 2 to 17, may include a number of other devices such as inductors, fuses, capacitors, coils, etc., while remaining within the scope of the present disclosure.

In brief overview, the method 100 starts with operation 102 of forming a stack of layers including a lower metal layer, an isolation material, and an upper metal layer. The method 100 continues to operation 104 of forming a first opening through the stack. The method 100 proceeds to operation 106 of lining the first opening first with a first channel layer and then with a first gate dielectric layer. The method 100 proceeds to operation 108 of forming a first dielectric spacer in the first opening. The method 100 proceeds to operation 110 of forming a first gate electrode in the first opening. The method 100 proceeds to operation 112 of forming a second dielectric spacer in the first opening. In various embodiments, the first gate electrode is vertically interposed between the first and second dielectric spacers, with the first channel layer wrapping around a combination of the first dielectric spacer, first gate electrode, and second dielectric spacer. The method 100 proceeds to operation 114 of forming a second opening through the stack. The method 100 proceeds to operation 116 of lining the second opening first with a second channel layer and then with a second gate dielectric layer. The method 100 proceeds to operation 118 of forming a third dielectric spacer in the second opening. The method 100 proceeds to operation 120 of forming a second gate electrode in the second opening. The method 100 proceeds to operation 122 of forming a fourth dielectric spacer in the second opening. In various embodiments, the second gate electrode is vertically interposed between the third and fourth dielectric spacers, with the second channel layer wrapping around a combination of the third dielectric spacer, second gate electrode, and fourth dielectric spacer. In various embodiments, upon operation 122 being performed, a first vertical transistor and a second vertical transistor can be formed in the first opening and the second opening, respectively. The method 100 proceeds to operation 124 of isolating the first vertical transistor and the second vertical transistor. The method 100 proceeds to operation 126 of forming a respective number of contact structures for each of the first vertical transistor and the second vertical transistor.

Corresponding to operation 102 of FIG. 1, FIG. 2 is a cross-sectional view of the semiconductor device 200 in which a stack 210 is formed over a substrate 202 at one of the various stages of fabrication, in accordance with various embodiments.

As shown, prior to forming the stack 210, a dielectric layer 204 is formed over the substrate 202. In some embodiments, the dielectric layer 204 (e.g., including silicon nitride) may serve as an etch stop layer when etching the stack 210. The stack 210 can include a lower metal layer 212, an isolation material 214 over the lower metal layer 212, and an upper metal layer 216 over the isolation material 214. As such, the lower metal layer 212 and the upper metal layer 216 may be electrically isolated from each other by the isolation material 214. Further, each of the lower metal layer 212, the isolation material 214, and the upper metal layer 216 may extend over the substrate 202 in multiple lateral directions.

The substrate 202 may be any semiconductor, insulator or conductor. In some embodiments, the substrate 202 comprises a semiconductor material such as silicon or germanium. The substrate 202 may also include a compound semiconductor such as silicon carbide, gallium arsenic, indium arsenide, and indium phosphide. The substrate 202 may include an alloy semiconductor such as silicon germanium, silicon germanium carbide, gallium arsenic phosphide, and gallium indium phosphide. In one embodiment, the substrate 202 includes an epitaxial layer. For example, the substrate 202 may have an epitaxial layer overlying a bulk semiconductor. Furthermore, the substrate 202 may include a semiconductor-on-insulator (SOI) structure. For example, the substrate 202 may include a buried oxide (BOX) layer formed by a process such as separation by implanted oxygen (SIMOX) or other suitable technique, such as wafer bonding and grinding.

In various embodiments, the lower metal layer 212 may be first formed (e.g., deposited) over the substrate 202, followed by the formation (e.g., deposition) of the isolation material 214 and then the upper metal layer 216. The metal layers 212 and 216, which may later be patterned as source and drain electrodes of one or more vertical transistors, may have a same metal material. The metal material may include copper, aluminum, or the like. The metal material may be deposited by CVD, physical vapor deposition (PVD), atomic layer deposition (ALD), and/or other suitable metal filling process. The isolation material 214 may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other isolation materials and/or other formation processes may be used. An anneal process may be performed once the isolation material is formed.

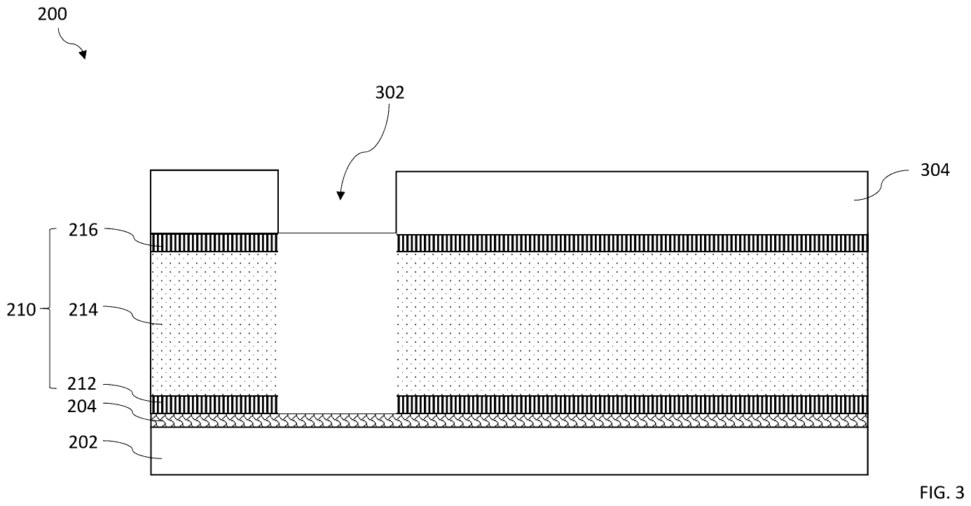

Corresponding to operation 104 of FIG. 1, FIG. 3 is a cross-sectional view of the semiconductor device 200 in which a first opening 302 is formed to extend through the stack 210 at one of the various stages of fabrication, in accordance with various embodiments. The first opening 302 is formed over a first region of the substrate 202.

Upon forming the stack 210, a patternable layer (e.g., a photoresist mask) 304 including one or more patterns can be formed thereupon. Next, following the patterns, an etching process (e.g., an anisotropic etching process) is performed to etch respective portions of the lower metal layer 212, the isolation material 214, and the upper metal layer 216, thereby forming the first opening 302. In some embodiments, the etching process can be stopped by the dielectric layer 204. As such, the first opening 302 can extend through the upper metal layer 216, the isolation material 214, and the lower metal layer 212. Alternatively stated, upon the first opening 302 is formed, respective inner sidewalls of the upper metal layer 216, the isolation material 214, and the lower metal layer 212 can be exposed. As will be shown in the top view of the semiconductor device 200 below, the first opening 302 can be formed with a circular shape. However, it should be understood that the first opening 302 can be formed in any of various shapes, while remaining within the scope of the present disclosure.

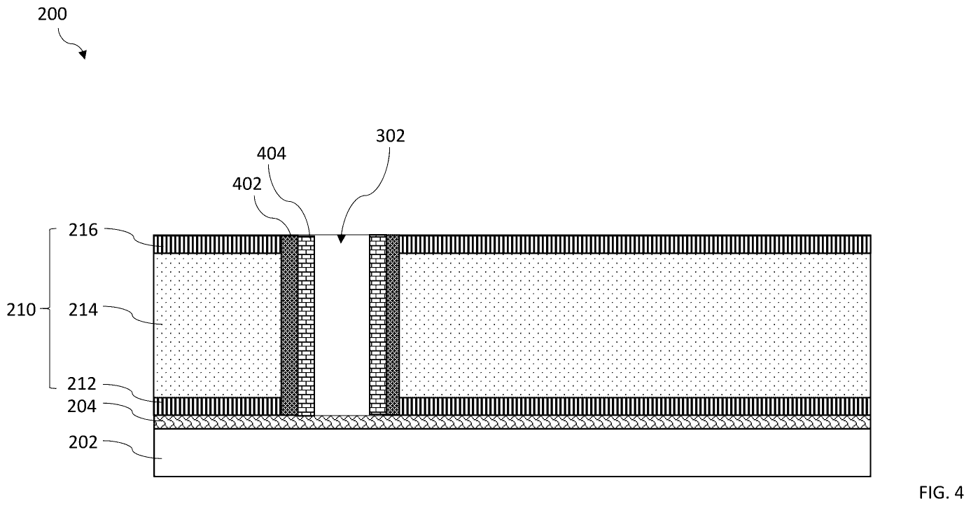

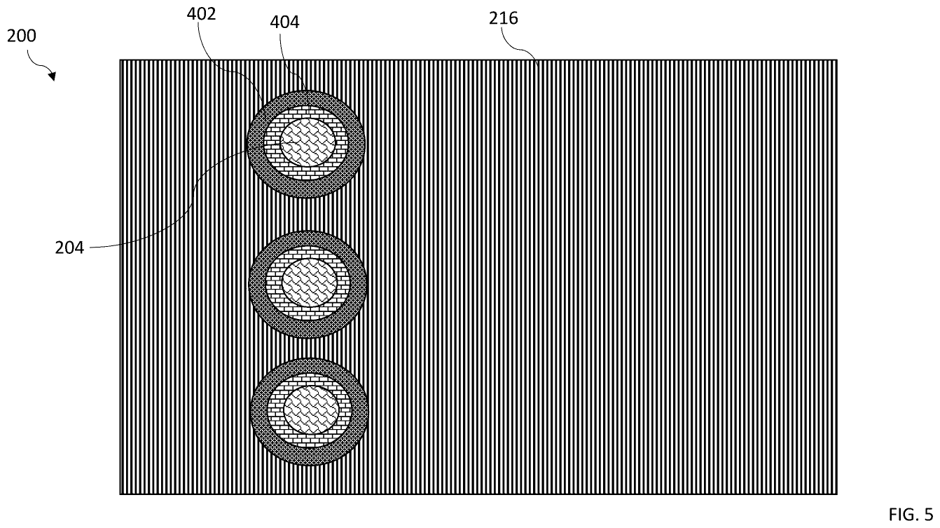

Corresponding to operation 106 of FIG. 1, FIG. 4 is a cross-sectional view of the semiconductor device 200 in which a first channel layer 402 and a first gate dielectric layer 404 are sequentially formed to line the first opening 302 at one of the various stages of fabrication, in accordance with various embodiments. Corresponding to the same operation 106, FIG. 5 is top view of the semiconductor device 200, which shows multiple first openings 302 formed through the stack 210. The first openings 302 are concurrently filled with the similar components, and thus, the following discussion will be focused on a single first opening 302.

As shown in FIGS. 4 and 5, the first channel layer 402 is first formed to surround inner sidewalls of the first opening 302, and the first gate dielectric layer 404 is further formed to surround inner sidewalls of the first channel layer 402. In various embodiments, after forming the first gate dielectric layer 404, the first opening 302 is not fully filled, allowing a pair of dielectric spacers and a gate electrode to be formed therein, which will be discussed in further detail below.

In some embodiments, the first channel layer 402 includes one or more semiconductive-behaving materials (e.g., conductive oxide materials), which may be formed using certain elements that, when combined with oxygen, form a new material that exhibits semiconductive behavior. For example, the semiconductive behaving material can be “turned off” and can have a low or practically no off-state leakage current, and the semiconductive behaving material can be “turned on” and become highly conductive when voltage is applied. Example materials to create an n-type channel for example include, but are not limited to, In₂O₃, SnO₂, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion. In one aspect of the present disclosure, the first channel layer 402 may be configured as a p-type channel.

The first gate dielectric layer 404 may be formed of a single high-k dielectric material, multiple different high-k dielectric materials, or multiple similar high-k dielectric materials. Example high-k dielectric materials include a metal oxide or a silicate of Hf, Al, Zr, La, Mg, Ba, Ti, Pb, and combinations thereof. The first gate dielectric layer 404 can be deposited using any suitable method, including, for example, molecular beam deposition (MBD), atomic layer deposition (ALD), PECVD, and the like. In some embodiments, the first gate dielectric layer 404 may optionally include a substantially thin oxide (e.g., SiOx) layer.

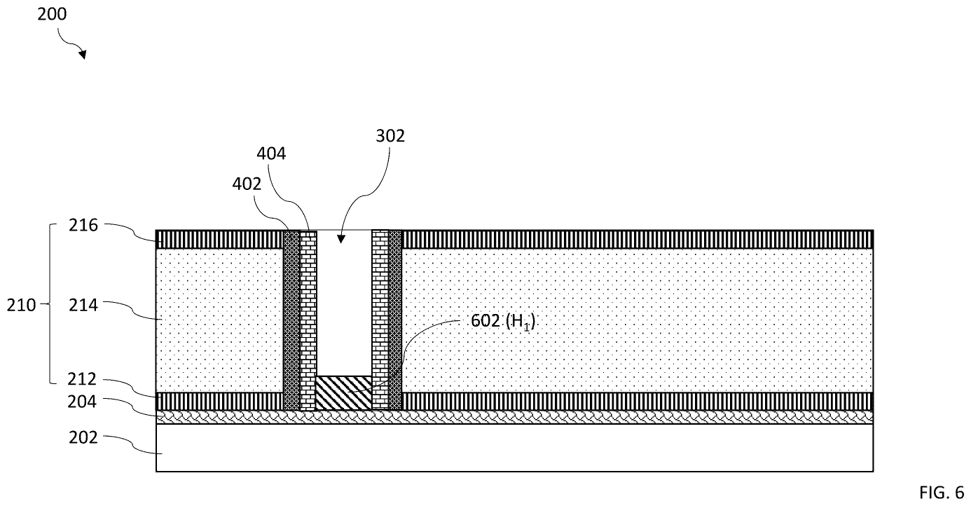

Corresponding to operation 108 of FIG. 1, FIG. 6 is a cross-sectional view of the semiconductor device 200 in which a first dielectric spacer 602 is formed in the first opening 302 at one of the various stages of fabrication, in accordance with various embodiments.

The first dielectric spacer 602 may be formed in the first opening 302 with a first height (H₁), thereby occupying a first portion of the first opening 302. The first dielectric spacer 602 may have an isolation material. The isolation material of the first dielectric spacer 602 may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other isolation materials and/or other formation processes may be used.

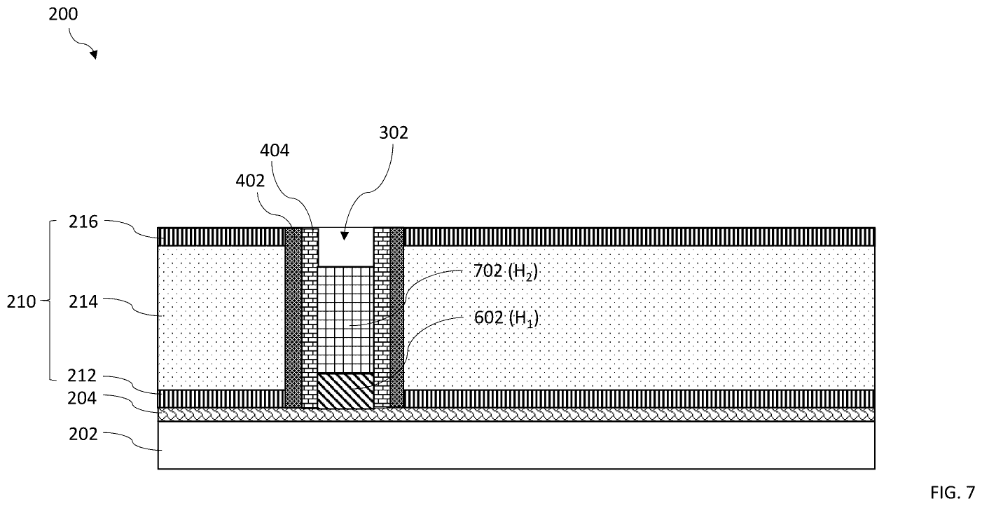

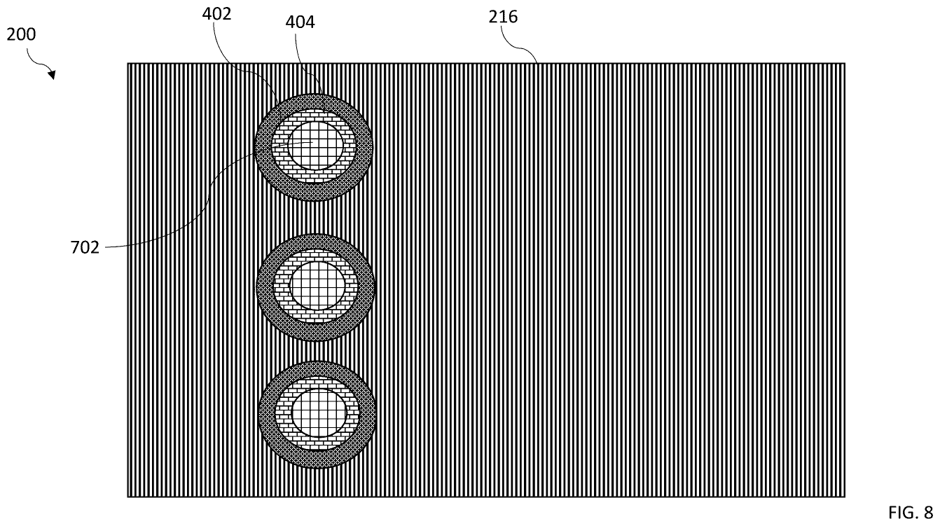

Corresponding to operation 110 of FIG. 1, FIG. 7 is a cross-sectional view of the semiconductor device 200 in which a first gate electrode 702 is formed in the first opening 302 at one of the various stages of fabrication, in accordance with various embodiments. Corresponding to the same operation 110, FIG. 8 is top view of the semiconductor device 200, which shows multiple first openings 302 formed through the stack 210. The first openings 302 are concurrently filled with the similar components, and thus, the following discussion will be focused on a single first opening 302.

The first gate electrode 702 may be formed in the first opening 302 with a second height (H₂), thereby occupying a second portion of the first opening 302. The first gate electrode 702 is formed over the first dielectric spacer 602, and thus, a bottom surface of the first gate electrode 702 is in contact with a top surface of the first dielectric spacer 602. The first gate electrode 702 may include a metal material. The metal material may include a work function metal that is configured to form, at least in part, the gate of a corresponding vertical transistor. For example, the first gate electrode 702 may include one or more p-type work function metals. Example p-type work function metals may include TiN, TaN, Ru, Mo, Al, WN, ZrSi2, MoSi2, TaSi2, NiSi2, WN, other suitable p-type work function materials, or combinations thereof. The work function metal(s) may be deposited by CVD, physical vapor deposition (PVD), ALD, and/or other suitable process.

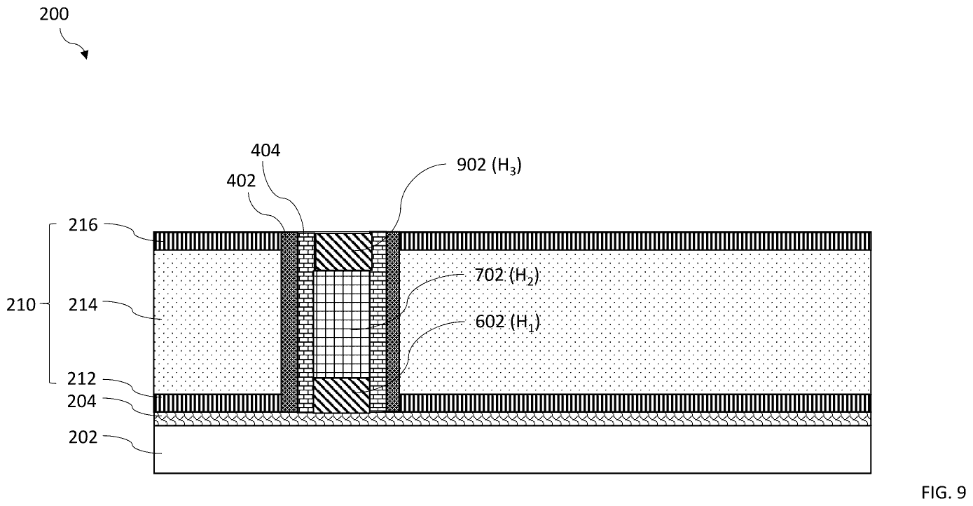

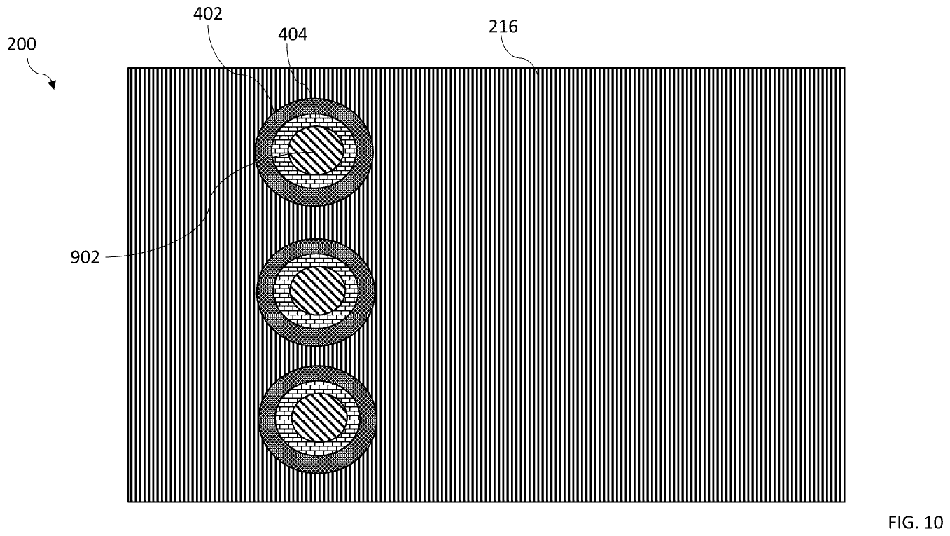

Corresponding to operation 112 of FIG. 1, FIG. 9 is a cross-sectional view of the semiconductor device 200 in which a second dielectric spacer 902 is formed in the first opening 302 at one of the various stages of fabrication, in accordance with various embodiments. Corresponding to the same operation 112, FIG. 10 is top view of the semiconductor device 200, which shows multiple first openings 302 formed through the stack 210. The first openings 302 are concurrently filled with the similar components, and thus, the following discussion will be focused on a single first opening 302.

The second dielectric spacer 902 may be formed in the first opening 302 with a third height (H₃), thereby occupying a third portion of the first opening 302. The second dielectric spacer 902 may have an isolation material. The isolation material of the second dielectric spacer 902 may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other isolation materials and/or other formation processes may be used.

The second dielectric spacer 902 is formed over the first gate electrode 702, and thus, a top surface of the first gate electrode 702 is in contact with a bottom surface of the second dielectric spacer 902. After forming the second dielectric spacer 902, the first channel layer 402 can surround a combination of the second dielectric spacer 902, the first gate electrode 702, and the first dielectric spacer 602, with a central portion of the first channel layer 402 wrapping around the first gate electrode 702. In various embodiments, the first dielectric spacer 602 is configured to vertically elevate the first gate electrode 702 from the lower metal layer 212 (e.g., to reduce capacitance coupled between the gate and one of the source or drain of a corresponding vertical transistor), and the second dielectric spacer 902 is configured to vertically lower the first gate electrode 702 from the upper metal layer 216 (e.g., to reduce capacitance coupled between the gate and the other source or drain of the corresponding vertical transistor).

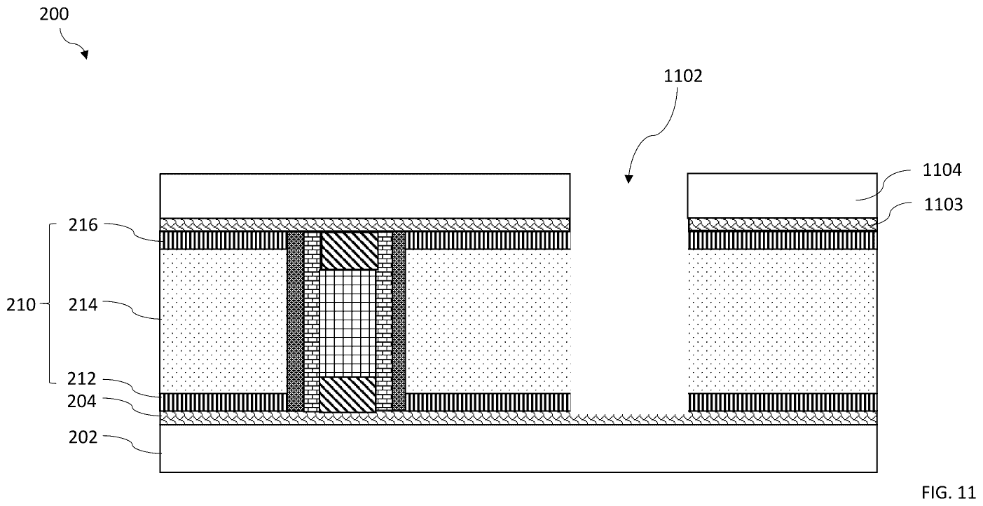

Corresponding to operation 114 of FIG. 1, FIG. 11 is a cross-sectional view of the semiconductor device 200 in which a second opening 1102 is formed to extend through the stack 210 at one of the various stages of fabrication, in accordance with various embodiments. The second opening 1102 is formed over a second region of the substrate 202, with respect to the first region where the first opening 302 is formed.

Upon forming the second dielectric spacer 902, a patternable layer (e.g., a photoresist mask) 1104 including one or more patterns can be formed on a dielectric layer 1103. Next, following the patterns, an etching process (e.g., an anisotropic etching process) is performed to etch respective portions of the lower metal layer 212, the isolation material 214, and the upper metal layer 216, thereby forming the second opening 1102. In some embodiments, the etching process can be stopped by the dielectric layer 204. As such, the second opening 1102 can extend through the upper metal layer 216, the isolation material 214, and the lower metal layer 212. Alternatively stated, upon the second opening 1102 is formed, respective inner sidewalls of the upper metal layer 216, the isolation material 214, and the lower metal layer 212 can be exposed. Similarly, the second opening 1102 can be formed with a circular shape. However, it should be understood that the second opening 1102 can be formed in any of various shapes, while remaining within the scope of the present disclosure.

In various embodiments, following operation 114, the method 100 continues to operation 116, 118, 120, 122, which are substantially similar to operations 106, 108, 110, and 112, respectively, except that a second channel layer is configured as an n-type channel and a second gate electrode with a second, different conductive type (n-type) is formed in the second opening 802.

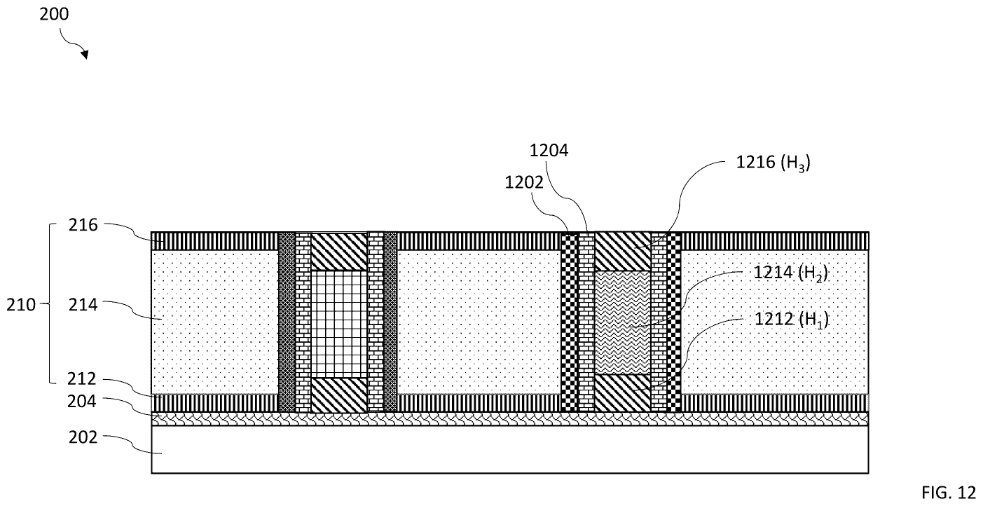

For example in a cross-sectional view of the semiconductor device 200 in FIG. 12, upon performing operation 116, a second channel layer 1202 and a second gate dielectric layer 1204 are sequentially formed in the second opening 1102. Next, operations 118, 120, and 122 are sequentially performed, which respectively form a third dielectric spacer 1212, a second gate electrode 1214, and a fourth dielectric spacer 1216 in the second opening 1102. As mentioned above, the second channel layer 1202 may be configured as an n-type channel, and the second gate electrode 1214 may include one or more n-type work function metals. Example n-type work function metals may include Ti, Ag, TaAl, TaAlC, TiAlN, TaC, TaCN, TaSiN, Mn, Zr, other suitable n-type work function materials, or combinations thereof. The work function metal(s) may be deposited by CVD, physical vapor deposition (PVD), ALD, and/or other suitable process.

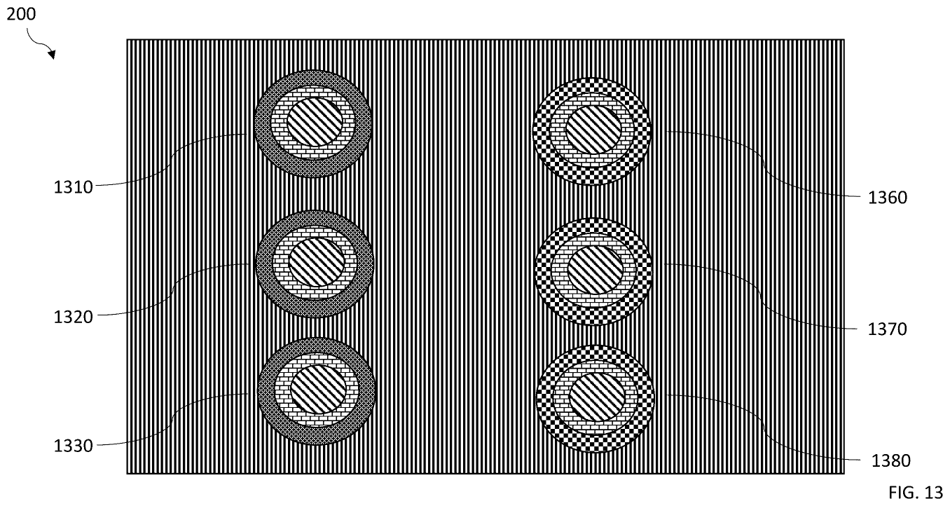

FIG. 13 is top view of the semiconductor device 200, which shows multiple first openings 302 and multiple second openings 1102 formed through the stack 210. Similar to the first openings 302, the second openings 1102 are concurrently filled with the similar components. Thus, upon performing operation 122, a number of first transistors 1310, 1320, and 1330, and a number of second transistors 1360, 1370, and 1380 are formed. In some embodiments, the first transistors 1310 to 1330 may each have a first conductive type (e.g., p-type), and the second transistors 1360 to 1380 may each have a second conductive type (e.g., n-type). Specifically, each of first transistors 1310, 1320, and 1330 includes a first gate electrode 702 (in p-type) surrounded by a first channel layer 402, which has its lower end portion and upper end portion respectively surrounded by the lower metal layer 212 and the upper metal layer 216; and each of the second transistors 1360, 1370, and 1380 includes a second gate electrode 1214 (in n-type) surrounded by a second channel layer 1202, which has its lower end portion and upper end portion respectively surrounded by the lower metal layer 212 and the upper metal layer 216.

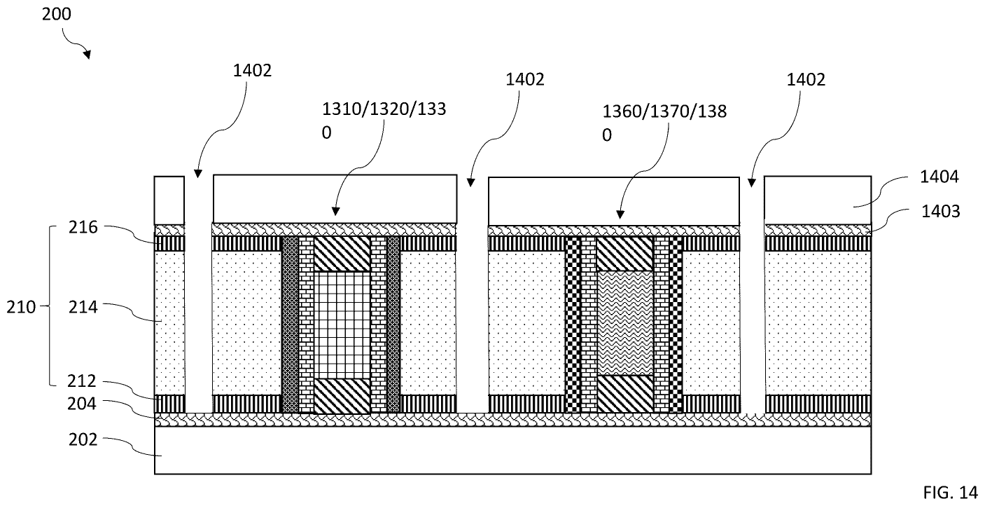

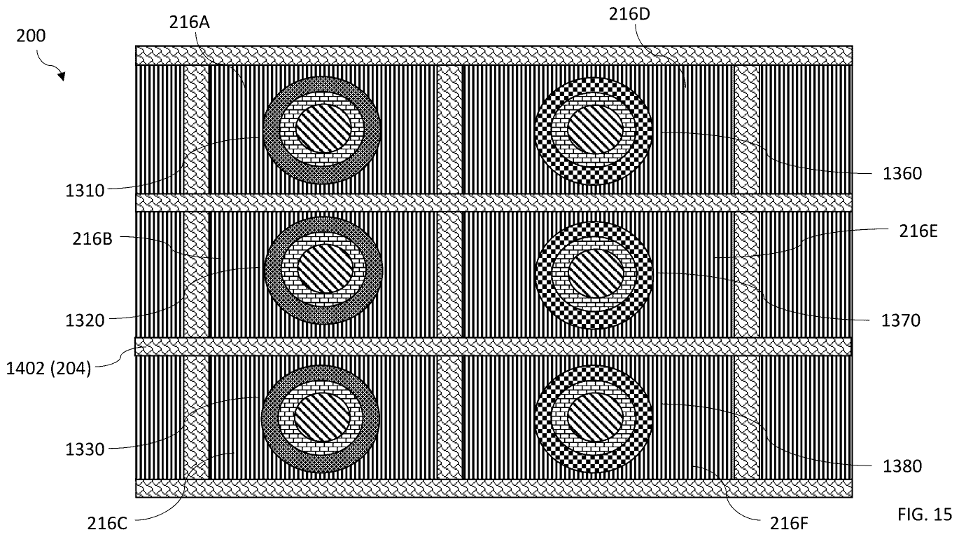

Corresponding to operation 124 of FIG. 1, FIG. 14 is a cross-sectional view of the semiconductor device 200 in which the first transistors 1310, 1320, and 1330, and the second transistors 1360, 1370, and 1380 are isolated from one another at one of the various stages of fabrication, in accordance with various embodiments. Corresponding to the same operation, FIG. 15 is a top view of the semiconductor device 200.

As shown in FIGS. 14 and 15, the lower metal layer 212 and the upper metal layer 216 may be separated into multiple discrete portions (e.g., 216A, 216B, 216C, 216D, 216E, 216F), each of which surrounds a corresponding one of the first transistors 1310, 1320, and 1330, and the second transistors 1360, 1370, and 1380. Such separated portions of the lower metal layer 212 and the upper metal layer 216 can function as a source electrode and a drain electrode for each of the first or second transistors, respectively, in some embodiments. For example in FIG. 15, portion 216A can function as a drain electrode of the transistor 1310; portion 216B can function as a drain electrode of the transistor 1320; portion 216C can function as a drain electrode of the transistor 1330; portion 216D can function as a drain electrode of the transistor 1360; portion 216E can function as a drain electrode of the transistor 1370; and portion 216F can function as a drain electrode of the transistor 1380.

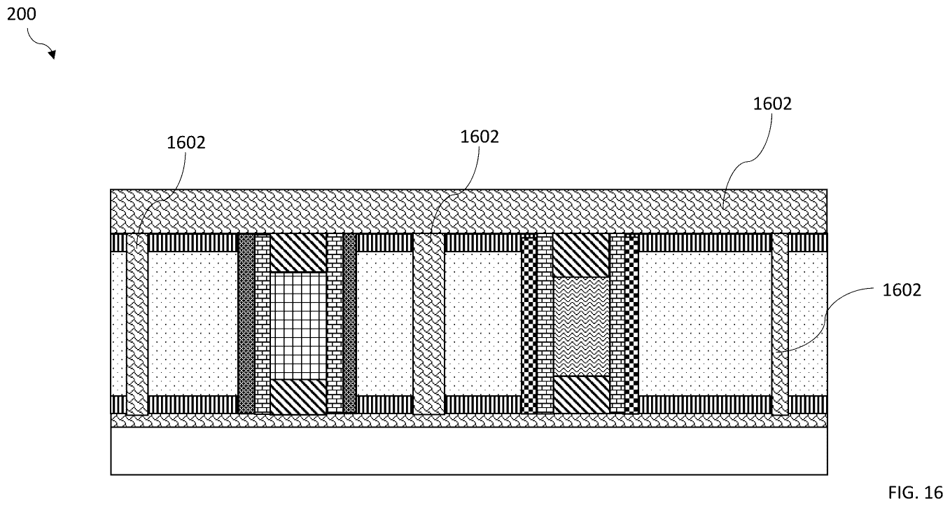

To form these source and drain electrodes, a patternable layer (e.g., a photoresist mask) 1404 including one or more patterns can be formed on a dielectric layer 1403. Next, following the patterns, an etching process (e.g., an anisotropic etching process) is performed to etch respective portions of the lower metal layer 212, the isolation material 214, and the upper metal layer 216, thereby isolating the source and drain electrodes of each first/second transistor from the source and drain electrodes of another first/second transistor. Specifically, with the etching process, a number of openings 1402 that extend through the stack 210 can be formed, which expose corresponding portions of the dielectric layer 204, respectively. The openings 1402 can then be filled with an isolation material 1602 (e.g., silicon oxide, silicon nitride, the like, or combinations thereof) and this isolation material 1602 can further overlay the workpiece with a certain thickness, as shown in a cross-sectional view of the semiconductor device 200 in FIG. 16.

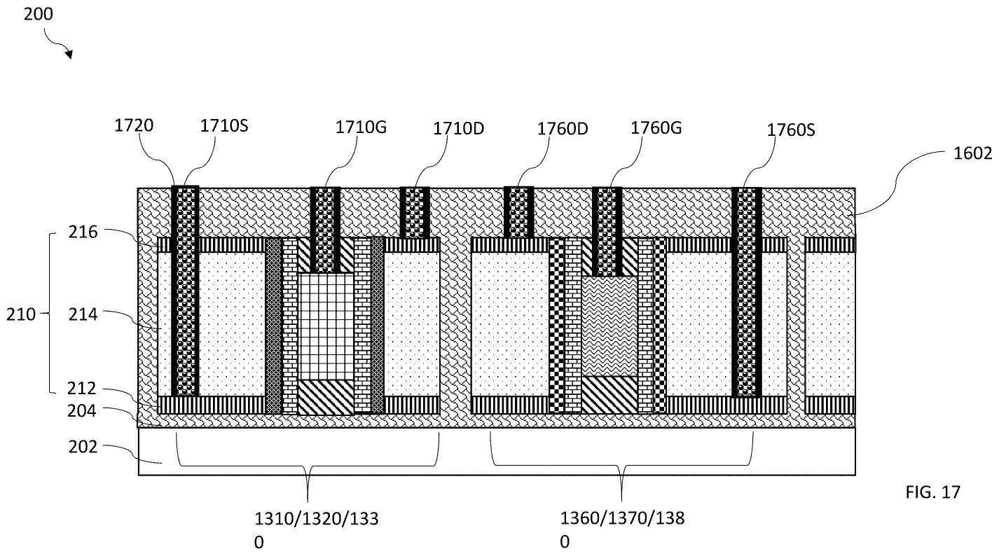

Corresponding to operation 126 of FIG. 1, FIG. 17 is a cross-sectional view of the semiconductor device 200 in which a number of contact structures 1710S, 1710G, and 1710D are formed for each of the first transistors 1310 to 1330 and a number of contact structures 1760S, 1760G, and 1760D for each of the second transistors 1360 to 1380 at one of the various stages of fabrication, in accordance with various embodiments.

Each of the contact structures 1710S, 1710G, 1710D, 1760S, 1760G, and 1760D is formed as a via structure that extends through one or more materials to be in contact with a respective conductive feature. For example, the contact structures 1710S and 1760S can each extend through the isolation material 214 to be in contact with the lower metal layer 211 of a corresponding transistor (functioning as its source electrode); the contact structures 1710D and 1760D can each extend through the isolation material 1602 to be in contact with the upper metal layer 216 of a corresponding transistor (functioning as its drain electrode); and the contact structures 1710G and 1760G can each extend through the isolation material 1602 and the corresponding dielectric spacer to be in contact with the gate electrode of a corresponding transistor.

Each of the contact structures 1710S, 1710G, 1710D, 1760S, 1760G, and 1760D includes at least one metal material. The metal material may include copper, aluminum, or the like. The metal material may be deposited by CVD, physical vapor deposition (PVD), atomic layer deposition (ALD), and/or other suitable metal filling process in a damascene process to form the contact structure. Further, at least some of the contact structures 1710S, 1710G, 1710D, 1760S, 1760G, and 1760D can each be surrounded by a dielectric material (e.g., 1720) to electrically isolate the contact structure from adjacent conductive feature(s), in some embodiments.

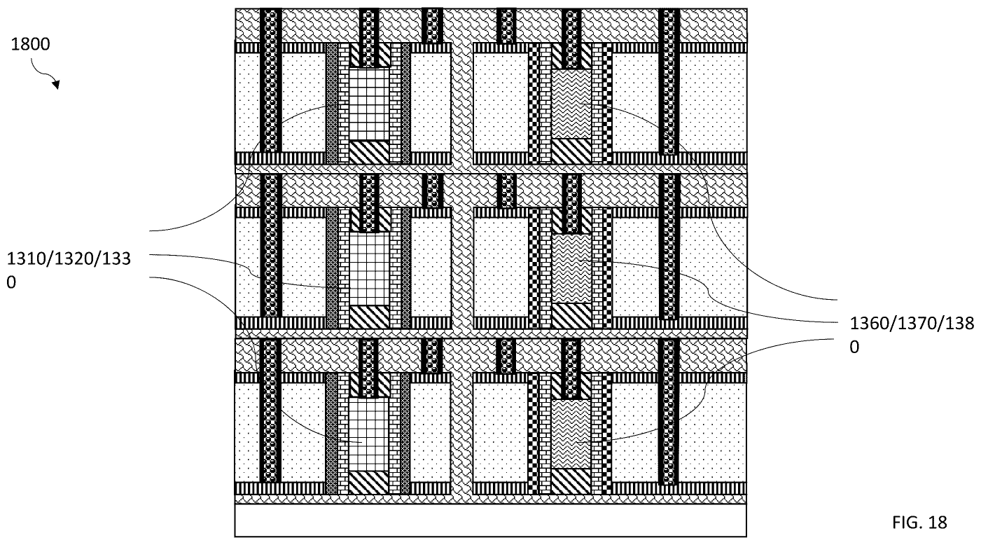

Based on the transistor structure discussed above, a number of transistors, with either the same conductive type or different conductive types, can be vertically stacked on top of one another. For example, FIG. 18 illustrates a cross-sectional view of another semiconductor device 1800 that includes a number of first transistors (e.g., 1310, 1320, 1330) with the first conductive type and a number of second transistors (e.g., 1360, 1370, 1380) with the second conductive type, in accordance with various embodiments. In particular, the same conductive type of the transistors may be vertically stacked on top of one another.

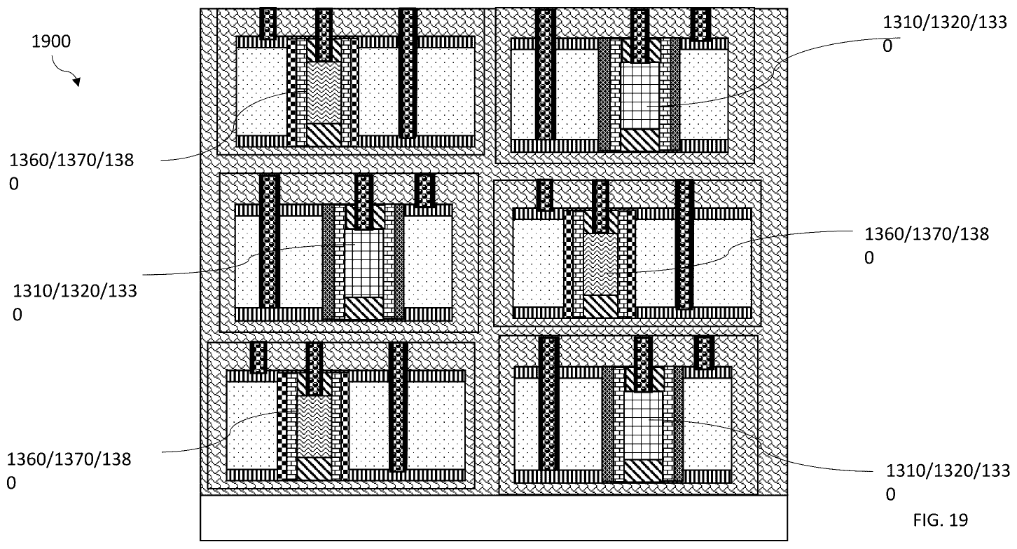

In another example, FIG. 19 illustrates a cross-sectional view of yet another semiconductor device 1900 that includes a number of first transistors (e.g., 1310, 1320, 1330) with the first conductive type stacked and a number of second transistors (e.g., 1360, 1370, 1380) with the second conductive type, in accordance with various embodiments. In particular, one of the first transistors may be vertically interposed between two of the second transistors, and one of the second transistors may be vertically interposed between two of the first transistors.

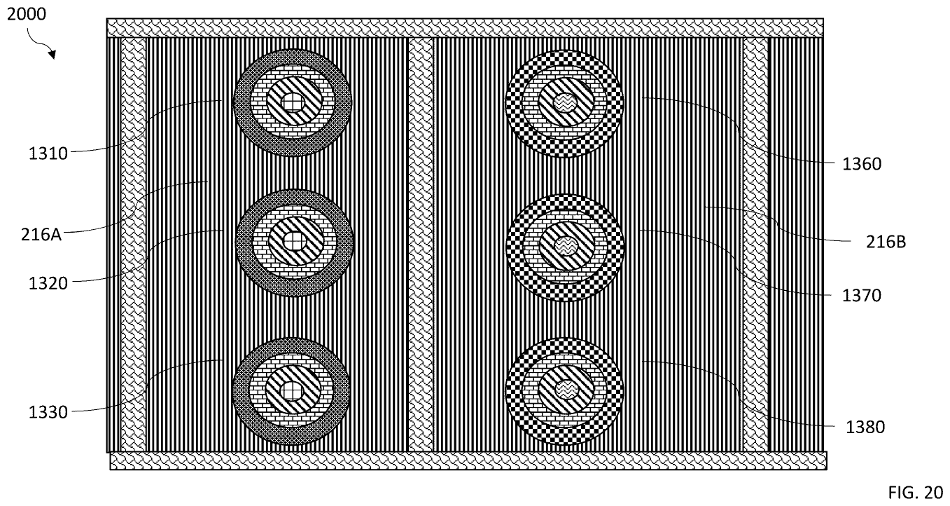

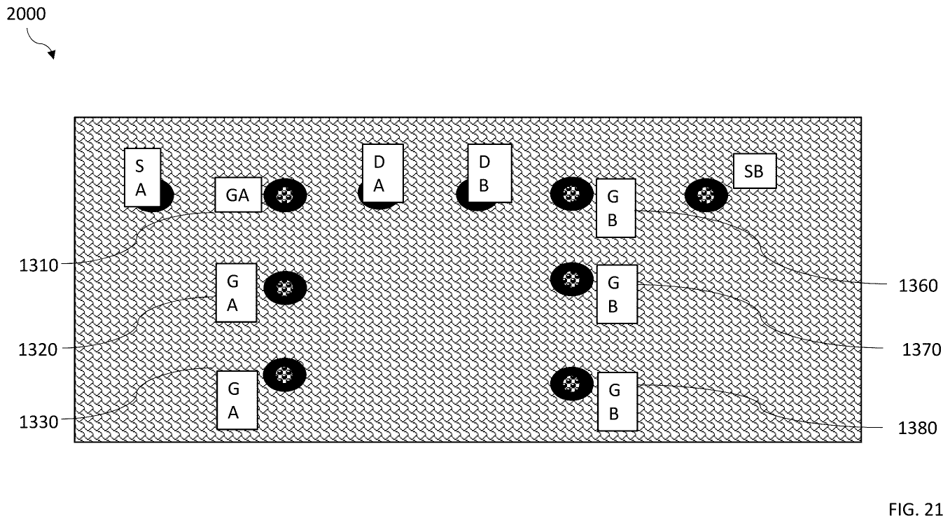

In some other embodiments, a plural number of transistors can share a respective pair of source electrode and drain electrode. For example, FIG. 20 illustrates a top view of yet another semiconductor device 2000 that includes a number of first transistors (e.g., 1310, 1320, 1330) with the first conductive type and a number of second transistors (e.g., 1360, 1370, 1380) with the second conductive type, in accordance with various embodiments. In particular, the first transistors 1310 to 1330 can share a same upper metal portion 216A (and a lower metal layer which is not shown), and the second transistors 1360 to 1380 can share a same upper metal portion 216B (and a lower metal layer which is not shown). Alternatively stated, in the example of FIG. 20, the first transistors 1310 to 1330 can have their source electrodes (a lower metal portion) electrically connected to one another, and their drain electrodes (the upper metal portion 216A) electrically connected to one another. Similarly, the second transistors 1360 to 1380 can have their source electrodes (another lower metal portion) electrically connected to one another, and their drain electrodes (the upper metal portion 216B) electrically connected to one another.

Based on the configuration shown in FIG. 20, the first transistors 1310 to 1330 can have respective contact structures connected to their gate electrodes (each labeled as “GA”), while sharing a same contact structure connected to their source electrodes (labeled as “SA”) and a same contact structure connected to their drain electrodes (labeled as “DA”). Similarly, the second transistors 1360 to 1380 can have respective contact structures connected to their gate electrodes (each labeled as “GB”), while sharing a same contact structure connected to their source electrodes (labeled as “SB”) and a same contact structure connected to their drain electrodes (labeled as “DB”). In some other embodiments, the different gate contact structures GAs may be further connected to each other through one or more metal layers (not shown), thereby shorting the gate electrodes of the first transistors 1310 to 1330. Similarly, the different gate contact structures GBs may be further connected to each other through one or more metal layers (not shown), thereby shorting the gate electrodes of the first transistors 1360 to 1380.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A structure, comprising:
a substrate including a first region and a second region;
a first lower metal layer and a first upper metal layer in the first region, wherein the first lower metal layer and the first upper metal layer are spaced from each other with a first isolation material;
a first channel extending from the first lower metal layer to the first upper metal layer;
a first gate electrode surrounded by the first channel and vertically spaced from each of the first lower metal layer and the first upper metal layer;
a second lower metal layer and a second upper metal layer in second region, wherein the second lower metal layer and the second upper metal layer are spaced from each other with a second isolation material;
a second channel extending from the second lower metal layer to the second upper metal layer; and
a second gate electrode surrounded by the second channel and vertically spaced from each of the second lower metal layer and the second upper metal layer.

2. The structure of claim 1, further comprising:
a first dielectric spacer disposed below the first gate electrode;
a second dielectric spacer disposed above the first gate electrode;
a third dielectric spacer disposed below the second gate electrode; and
a fourth dielectric spacer disposed above the second gate electrode.

3. The structure of claim 2, wherein the first and second dielectric spacers are each surrounded by the first channel, and the third and fourth dielectric spacers are each surrounded by the second channel.

4. The structure of claim 2, wherein the first dielectric spacer elevates a bottom surface of the first gate electrode away from the first lower metal layer, and the second dielectric spacer lowers a top surface of the first gate electrode away from the first upper metal layer.

5. The structure of claim 2, wherein the third dielectric spacer elevates a bottom surface of the second gate electrode away from the second lower metal layer, and the fourth dielectric spacer lowers a top surface of the second gate electrode away from the second upper metal layer.

6. The structure of claim 1, wherein the first gate electrode has a first conductive type, and the second gate electrode has a second conductive type.

7. The structure of claim 1, further comprising:
a first gate dielectric extending from the first lower metal layer to the first upper metal layer, and surrounded by the first channel; and
a second gate dielectric extending from the second lower metal layer to the second upper metal layer, and surrounded by the second channel.

8. The structure of claim 1, wherein the first channel includes at least one of: indium oxide (In₂O₃), tin dioxide (SnO₂), zinc oxide (ZnO), or InGaZnO, and the second channel includes tin oxide (SnO).

9. The structure of claim 1, further comprising:
a first via structure extending through the first upper metal layer and the first isolation material, and in electrical contact with the first lower metal layer;
a second via structure extending through a dielectric spacer disposed above the first gate electrode, and in electrical contact with the first gate electrode;
a third via structure in electrical contact with the first upper metal layer;
a fourth via structure extending through the second upper metal layer and the second isolation material, and in electrical contact with the second lower metal layer;
a fifth via structure extending through a dielectric spacer disposed above the second gate electrode, and in electrical contact with the second gate electrode; and
a sixth via structure in electrical contact with the second upper metal layer.

10. A structure, comprising:
a first lower metal layer extending along one or more lateral directions;
a first upper metal layer in parallel with the first lower metal layer, wherein the first lower metal layer and the first upper metal layer are spaced from each other with a first isolation material;
a first channel extending from the first lower metal layer to the first upper metal layer;
a first dielectric spacer surrounded by the first channel and further by the first lower metal layer;
a second dielectric spacer also surrounded by the first channel and further by the first upper metal layer; and
a first gate electrode surrounded by the first channel and vertically interposed between the first dielectric spacer and the second dielectric spacer.

11. The structure of claim 10, wherein the first dielectric spacer elevates a bottom surface of the first gate electrode away from the first lower metal layer, and the second dielectric spacer lowers a top surface of the first gate electrode away from the first upper metal layer.

12. The structure of claim 10, further comprising a first gate dielectric extending from the first lower metal layer to the first upper metal layer, and interposed between the first channel and a combination of the first dielectric spacer, the first gate electrode, and the second dielectric spacer.

13. The structure of claim 10, further comprising:
a second lower metal layer extending along the one or more lateral directions;
a second upper metal layer in parallel with the second lower metal layer, wherein the second lower metal layer and the second upper metal layer are spaced from each other with a second isolation material;
a second channel extending from the second lower metal layer to the second upper metal layer;
a third dielectric spacer surrounded by the second channel and further by the second lower metal layer;
a fourth dielectric spacer also surrounded by the second channel and further by the second upper metal layer; and
a second gate electrode surrounded by the second channel and vertically interposed between the third dielectric spacer and the fourth dielectric spacer.

14. The structure of claim 13, wherein the first gate electrode has a first conductive type, and the second gate electrode has a second conductive type.

15. The structure of claim 10, further comprising:
a third lower metal layer extending along the one or more lateral directions;
a third upper metal layer in parallel with the third lower metal layer, wherein the third lower metal layer and the third upper metal layer are spaced from each other with a third isolation material;
a third channel extending from the third lower metal layer to the third upper metal layer;
a fifth dielectric spacer surrounded by the third channel and further by the third lower metal layer;
a sixth dielectric spacer also surrounded by the third channel and further by the third upper metal layer; and
a third gate electrode surrounded by the third channel and vertically interposed between the fifth dielectric spacer and the sixth dielectric spacer;
wherein the first gate electrode and the third gate electrode have an identical conductive type.

16. The structure of claim 15, wherein the first lower metal layer and the third lower metal layer are formed as a first one-piece structure, and the first upper metal layer and the third upper metal layer are formed as a second one-piece structure.

17. The structure of claim 15, wherein the first lower metal layer and the third lower metal layer are isolated from each other, and the first upper metal layer and the third upper metal layer are isolated from each other.

18. A method, comprising:
forming a stack including a lower metal layer, an isolation material, and an upper metal layer, wherein the lower metal layer and the upper metal layer are spaced from each other with the isolation material;
forming a first opening extending through the stack;
lining an inner sidewall of the first opening with a first channel; and
sequentially forming a first dielectric spacer, a first gate electrode, and a second dielectric spacer in the first opening, wherein a combination of the first dielectric spacer, the first gate electrode, and the second dielectric spacer is surrounded by the first channel.

19. The method of claim 18, wherein the first dielectric spacer elevates a bottom surface of the gate electrode away from the lower metal layer, and the second dielectric spacer lowers a top surface of the gate electrode away from the upper metal layer.

20. The method of claim 18, further comprising:
forming a second opening extending through the stack;
lining an inner sidewall of the second opening with a second channel; and
sequentially forming a third dielectric spacer, a second gate electrode, and a fourth dielectric spacer in the second opening, wherein a combination of the third dielectric spacer, the second gate electrode, and the fourth dielectric spacer is surrounded by the second channel.
